(19) United States
(12) Patent Application Publication
(10) Pub. No.: US 2012/0175671 A1
(43) Pub. Date: Jul. 12, 2012

(54) Glued light core for light-emitting diode

(76) Inventor: Han-Ming Lee, Hsinchu City (TW)

(21) Appl. No.: 12/930,417

(22) Filed: Jan. 7, 2011

(51) Int. Cl. H01L 33/56

(52) U.S. Cl. 257/100; 257/E33.059

(57) ABSTRACT

The present invention relates to an improved glued light core for a light-emitting diode (LED), which provides an optical lamp body integrally formed on an upper end of an LED lead frame. In particular, the optical lamp body is designed as a glued structure with minimal epoxy, to simplify a complicated packaging operation in a conventional manufacturing process, to directly fasten a crystal cup, a crystal cell and a conductive gold wire to the upper end of the lead frame by the epoxy, and to provide illumination comparable to that of general light core. Additionally, a light-emitting housing is made of polychloroprene or plastic resin which is able to be applied or injected outside the glued light core, such that a light source inside the glued light core emits light beams through the light-emitting housing to form collection or stray lights of a special light source with multiple variations. Thus, the manufacturing process and multiple applications of the LED can be greatly simplified.

### BACKGROUND OF THE INVENTION

As shown in FIG. 1, in a conventional LED lamp, a crystal cell and a gold wire are disposed at an upper end of a lead frame, and the assembled crystal cell, the gold wire and the lead frame have to pass through processes for epoxy package in an injection mold.

Thus, an integrally-formed LED lamp is obtained, and a refraction of light, which delivers efficiency, can be achieved when the crystal cell emits light beam through the epoxy package structure. It is time-consuming and costly for the cooling process of the injected glue, which further raises the manufacturing cost and compromises the market competitiveness. Therefore, it is required to simplify the structure of the conventional LED lamp.

### SUMMARY OF THE INVENTION

A main purpose of the invention is to provide a glued light core for an LED, and in particular, to apply glue at an outer circumference of a crystal cup, a crystal cell and a conductive gold wire which are located at an upper end of a lead frame for fixation. It aims to provide illumination comparable to that of general light core and to simplify the complicated packaging operation in a conventional manufacturing process.

A secondary purpose of the invention is to provide a glued light core for an LED, which is equipped with a housing capable of application outside the glued light core. As a result, a light source inside the glued light core may emit light beams through the light-emitting housing to form collection or stray lights of a special light source with multiple variations.

Another purpose of the invention is to provide a glued light core for an LED, and in particular, to apply glue at an outer circumference of a crystal cup and a crystal cell which are located at an upper end of a lead frame for fixation, with the aim to simplify the design.

### BRIEF DESCRIPTION OF THE DRAWINGS

FIG. 1 is a schematic of the traditional structure.

FIG. 2 is a 3D diagram of the present invention.

FIG. 3 is a schematically exploded perspective view of the present invention.

FIG. 4 is a schematic view of an application of the present invention.

FIG. 5 is a schematic view of another application of the present invention.

### DELTAILED DESCRIPTION OF THE PREFERRED EMBODIMENT

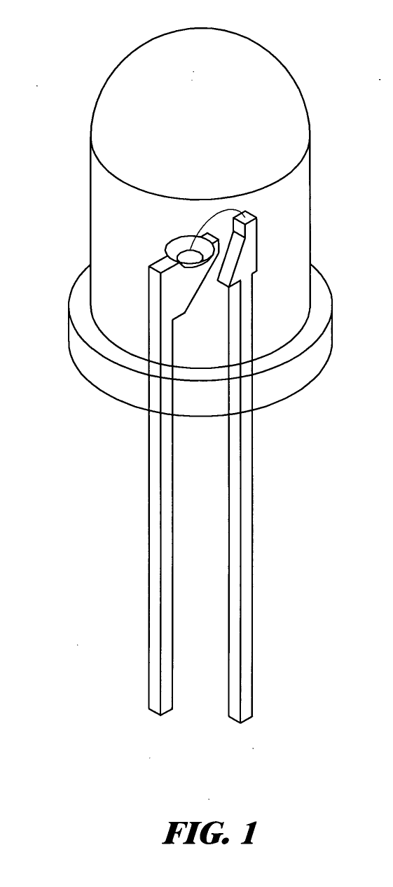

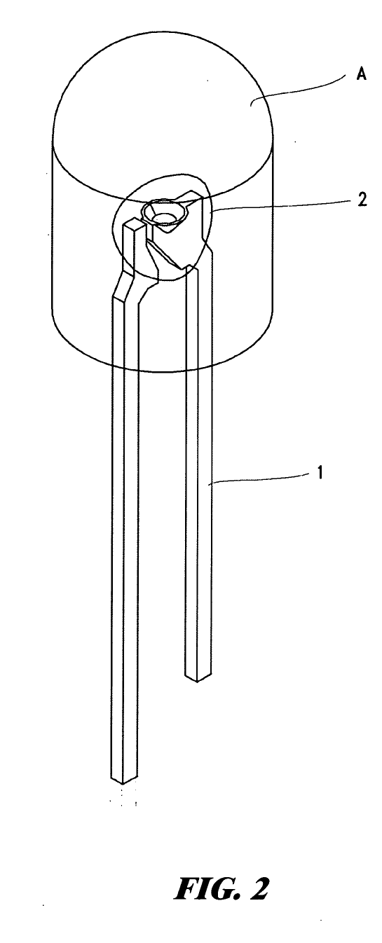

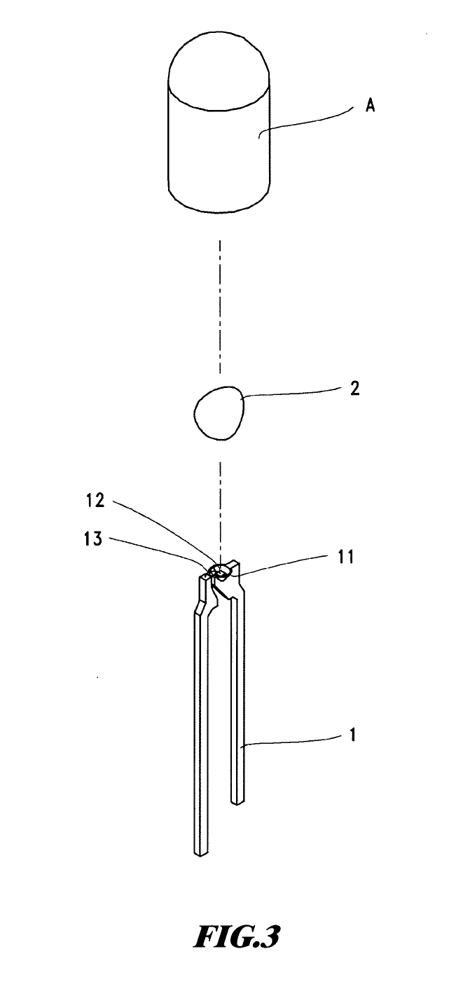

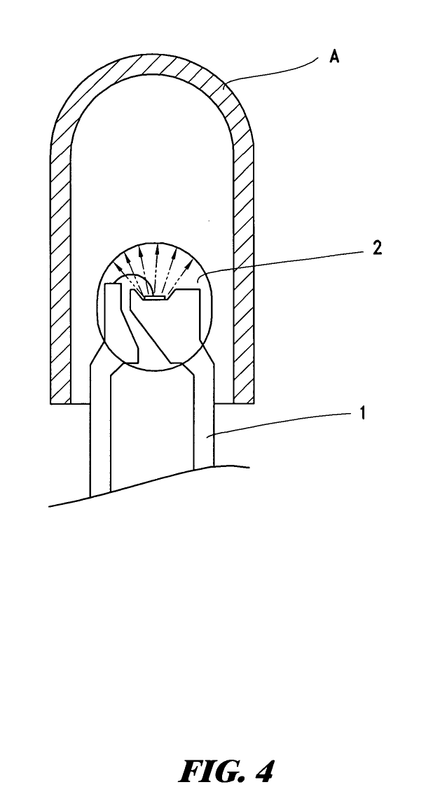

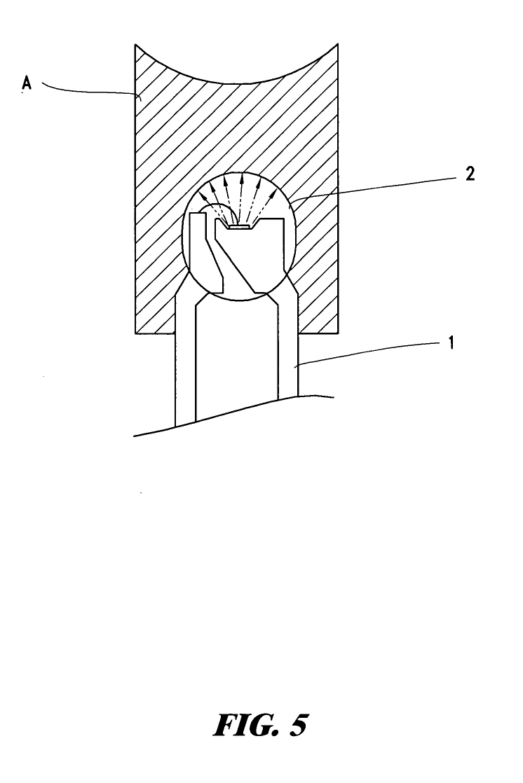

According to FIGS. 1 to 5, an improved glued light core for an LED of the invention is characterized in that minimal epoxy 2 is glued at an outer circumference of a crystal cup 11, a crystal cell 12 and a conductive gold wire 13 which are located at an upper end of a conventional lead frame 1 to simplify the complicated packaging operation in a conventional manufacturing process and to provide illumination comparable to that of general light core.

In an embodiment of the invention, with the droplet-like minimal epoxy 2 applied on the glued light core, a light-emitting housing “A” is made of polychloroprene or plastic resin which is applied or injected outside the glued light core, such that a light source inside the glued light core emits light beams through the light-emitting housing to form collection or stray lights of a special light source with multiple variations. Thus the manufacturing process and multiple applications of the LED can be greatly simplified.

I claim:

1. An improved glued light core for an LED is characterized in that minimal epoxy is glued at an outer circumference of a crystal cup, a crystal cell and a conductive gold wire which are located at an upper end of a lead frame to simplify a complicated packaging operation in a conventional manufacturing process and to provide illumination comparable to that of general light core. Furthermore, a light-emitting housing is made of polychloroprene or plastic resin which is applied or injected outside the glued light core, such that a light source inside the glued light core emits light beams through the light-emitting housing to form collection or stray lights of a special light source with multiple variations.
